(19) United States
(12) Patent Application Publication
(10) Pub. No.: US 2025/0107426 A1
(43) Pub. Date: Mar. 27, 2025

(54) DISPLAY DEVICE

(71) Applicant: Japan Display Inc., Tokyo (JP)

(72) Inventor: Tatsuya IDE, Tokyo (JP)

(73) Assignee: Japan Display Inc., Tokyo (JP)

(21) Appl. No.: 18/890,769

(22) Filed: Sep. 20, 2024

(30) Foreign Application Priority Data
Sep. 21, 2023 (JP) 2023-155517

(51) Int. Cl. H10K 77/10; H10K 59/131; H10K 102/00

(52) U.S. Cl. CPC H10K 77/111; H10K 59/131; H10K 2102/311

(57) ABSTRACT

According to one embodiment, a display device includes a flexible base, a first insulating layer provided on the base, a wiring line provided on the first insulating layer, and a second insulating layer which covers the wiring line and the first insulating layer. The display device includes a display area and an end portion region including a bend area, the second insulating layer includes a first region having a first thickness and a second region having a second thickness greater than the first thickness, the second region overlaps the bend area, and a neutral plane of a stacked structure of the base, the first insulating layer, the wiring line, and the second insulating layer is created in the wiring line.

### CROSS-REFERENCE TO RELATED APPLICATION

This application is based upon and claims the benefit of priority from Japanese Patent Application No. 2023-155517, filed Sep. 21, 2023, the entire contents of which are incorporated herein by reference.

### FIELD

Embodiments described herein relate generally to a display device.

### BACKGROUND

Flat panel displays, such as organic electroluminescence (EL) displays, have display panels in which a thin film transistor (TFT), organic light-emitting diode (OLED) and the like are formed on a substrate. For the base of such display panels, a glass substrate is conventionally used, but, in recent years, flexible displays with bendable display panels has been developed increasingly by using a resin film as the base.

As an application of such flexible displays, a part of the display panel that is provided on an outer side the image display area and on which an integrated circuit (IC) or flexible printed circuit (FPC) is mounted is bent to the backside of the display area. This attempt is considered to achieve a narrower frame.

### BRIEF DESCRIPTION OF THE DRAWINGS

FIG. 1 is an overall perspective view showing a display device according to an embodiment.

FIG. 2 is a cross-sectional view showing an example of a brief configuration of a display panel in a comparative example.

FIG. 3 is a cross-sectional view showing an example of a brief configuration of a display panel in a comparative example.

FIG. 4 is a partial enlarged cross-sectional view of what is shown in FIG. 2.

FIG. 5 is a cross-sectional view showing a display device of another comparative example.

FIG. 6 is a cross-sectional view showing a display device of still another comparative example.

FIG. 7 is a partial enlarged cross-sectional view of a bend area.

FIG. 8 is a diagram illustrating the relationship between a radius of curvature and a distance from a lower surface of a base to a neutral plane when a display device is bent.

FIG. 9 is a diagram illustrating the relationship between the radius of curvature and the distance from the lower surface of the base to the neutral plane when a display device is bent.

FIG. 10 is a diagram illustrating the relationship between the radius of curvature and the distance from the lower surface of the base to the neutral plane when the display device of the embodiment is bent.

FIG. 11 is a cross-sectional view showing an example of a brief configuration of the display panel of the embodiment.

FIG. 12 is a partial plan view schematically showing an example of a configuration of the display panel.

FIG. 13 is a cross-sectional view of the display panel shown in FIG. 12 taken along the line A1-A2.

### DETAILED DESCRIPTION

In general, according to one embodiment, a display device comprises
a flexible base;

a first insulating layer provided on the base;
a wiring line provided on the first insulating layer; and
a second insulating layer which covers the wiring line and the first insulating layer, wherein
the display device includes a display area and an end portion region including a bend area,
the second insulating layer includes a first region having a first thickness and a second region having a second thickness greater than the first thickness,
the second region overlaps the bend area, and
a neutral plane of a stacked structure of the base, the first insulating layer, the wiring line, and the second insulating layer are formed in the wiring line.

An object of this embodiment is to provide a display device which can suppress the lowering of the yield.

Embodiments will be described hereinafter with reference to the accompanying drawings. Note that the disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

The embodiments described herein are not general ones, but rather embodiments that illustrate the same or corresponding special technical features of the invention. The following is a detailed description of one embodiment of a display device with reference to the drawings.

In this embodiment, a first direction X, a second direction Y and a third direction Z are orthogonal to each other, but may intersect at an angle other than 90 degrees. The direction toward the tip of the arrow in the third direction Z is defined as up or above, and the direction opposite to the direction toward the tip of the arrow in the third direction Z is defined as down or below. Note that the first direction X, the second direction Y and the third direction Z may as well be referred to as an X direction, a Y direction and a Z direction, respectively.

Further, with such expressions as “the second member above the first member” and “the second member below the first member”, the second member may be in contact with the first member or may be located away from the first member. In the latter case, a third member may be interposed between the first member and the second member. On the other hand, with such expressions as “the second member on the first member” and “the second member beneath the first member”, the second member is in contact with the first member.

Furthermore, it is assumed that there is an observation position to observe the optical control element on a tip side of the arrow in the third direction Z. Here, viewing from this observation position toward the X-Y plane defined by the first direction X and the second direction Y is referred to as plan view. Viewing a cross-section of the display device in the X-Z plane defined by the first direction X and the third direction Z or in the Y-Z plane defined by the second direction Y and the third direction z is referred to as cross-sectional view.

### Embodiment

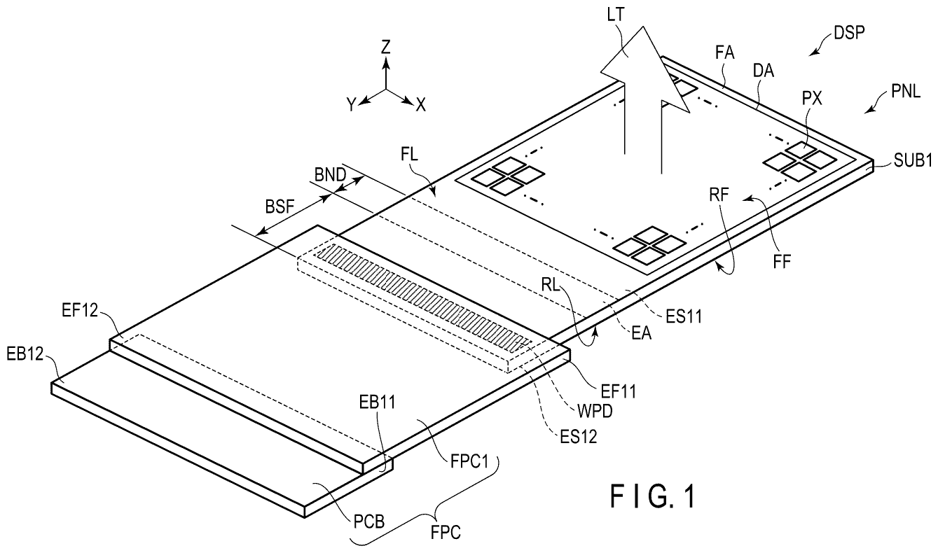

FIG. 1 is an overall perspective view showing a display device according to an embodiment. A display device DSP comprises a display area DA and a peripheral area FA provided around the display area DA on a substrate SUB1, provided therein. The display device DSP includes a plurality of pixels PX arranged in the display area DA. In the display device DSP, light LT of each pixel PX is emitted upward.

In FIG. 1, a display panel PNL is constituted by the substrate SUB1, the plurality of pixels PX, and the like. The surface of the display panel PNL that emits the light LT is referred to as a surface FF. The surface on an opposite side to the surface FF in the third direction Z is referred to as a surface RF. The surface FF may be defined as an emission surface, front surface, or upper surface, and the surface RF may be defined as a rear surface or lower surface.

An area EA in an end portion of the substrate SUB1 is located on an outer side the display area DA. Of the area EA, a region close to the display area DA is referred to as an end portion ES11. Of the area region EA, an end portion that is spaced apart from the display area DA along the second direction Y is referred to as an end portion ES12. Of the surfaces of the substrate SUB1, the one that emits the light LT is referred to as a surface FL. The surface on an opposite side to the surface FL is referred to as a surface RL. The surface RL is the same surface as the surface RF. Note that the area EA may as well be referred to as an end portion region of the display panel PNL.

In the area EA on an end portion ES12 side, a connection portion WPD is provided. To the connection portion WPD, wiring lines from the display area DA extend. The wiring lines from the display area DA include scanning lines or signal lines from the pixels PX or wiring lines connected to the scanning lines or signal lines.

Between the end portion ES11 and the end portion ES12 of the area EA, an area BND is provided. Between the area BND and the end portion ES12, an area BSF is provided. The area BND is a bend area, and the area BSF is an area that is turned upside down when bent. The areas BND and BSF will be described in detail later.

A flexible wiring board FPC1 is provided in the connection portion WPD of the area EA. The flexible wiring board FPC1 includes a plurality of wiring lines aligned along the first direction X. The wiring lines of the flexible wiring board FPC1 are electrically connected to the connection portion WPD by an anisotropic conductive film (ACF). With this configuration, the wiring lines from the display area DA and the wiring lines from the flexible wiring board FPC1 are electrically connected respectively to each other.

The end portion of the flexible wiring board FPC1, which is close to the connection portion WPD is referred to as an end portion EF11. The end portion on an opposite side to the end portion EF11 along the second direction Y is referred to as an end portion EF12. The end portion EF11 is closer to the end portion ES12 of the substrate SUB1 than from the end portion EF12. In other words, the end portion EF11 is located between the end portion EF12 and the end portion ES12.

The end portion EF12 of the flexible wiring board FPC1 is electrically connected to the printed circuit board PCB. The end portion of the printed circuit board PCB, which is connected to the end portion EF12 of the flexible wiring board FPC1 is referred to as an end portion EB11. The end portion on an opposite side to the end portion EB11 along the second direction Y is referred to as an end portion EB12. The end portion EB11 is closer to the end portion ES12 of the substrate SUB1 than from the end portion EB12. In other words, the end portion EB11 is located between the end portion EB12 and the end portion ES12.

Note that the flexible wiring board FPC1 and the printed circuit board PCB may be referred to as flexible wiring boards FPC in general. Alternatively, the printed circuit board PCB may not be provided, and such a configuration may do that only the flexible wiring board FPC1 is provided.

The flexible wiring board FPC1 may be provided with a drive element that outputs video signals and drive signals. Signals from the drive element are input to the pixels PX in the display area DA via the flexible wiring board FPC1. Based on the video signals and various control signals, the pixels PX emit light.

The substrate SUB1 comprises a flexible base (base BA1 to be described later) and a plurality of pixels PX. The base may be formed, for example, of a resin film material, more specifically, acrylic, polyimide, polyethylene terephthalate, polyethylene naphthalate, or the like. On the base, a plurality of pixels PX are provided, which include a plurality of switching elements, a plurality of scanning lines, a plurality of signal lines, a plurality of pixel electrodes, a common electrode, a plurality of light emitting layers, and the like. The detailed configuration of the pixels PX and the like will be described later.

Since the substrate SUB1 has flexibility, the display panel PNL is a flexible display panel. In other words, the display panel PNL is a flexible display.

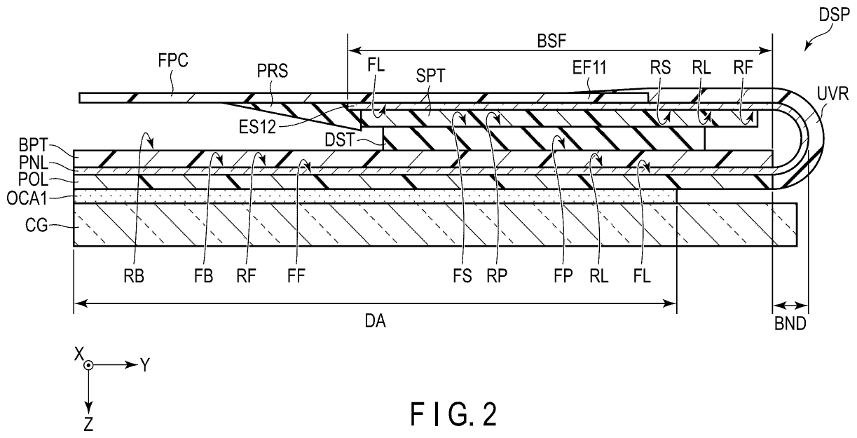

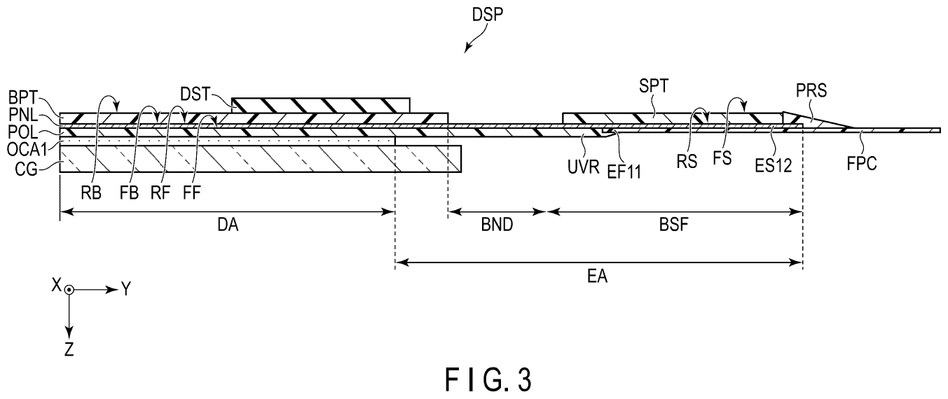

Here, a display device of a comparative example will be described. FIGS. 2 and 3 are cross-sectional views schematically showing an example of the configuration of the display device of the comparative example. FIG. 2 is a cross-sectional view showing the display device of the comparative example in a bent state. FIG. 3 is a cross-sectional view of the display device of the comparative example in a state before being bent.

The display device DSP comprises a display panel PNL, a polarizer POL, an optical adhesive OCA1, a cover member CG, a protective member BPT, a protective member UVR, a protective member PRS, a protective member DST, and a flexible circuit board FPC.

In the display device DSP shown in FIG. 2, the display panel PNL is bent in the area BND. By bending the display panel PNL in the area BND, the area EA including the connection part WPD becomes smaller, thereby making it possible to narrow the frame more.

The area BSF of the display panel PNL is placed to overlap a part of the display area DA in an opposite direction to the third direction Z. Between the part of the display area DA and the area BSF, a protective member BPT, a protective member DST and a protective member SPT are arranged along a direction opposite to the third direction Z.

A polarizer POL is provided on an surface FF side of the display panel PNL so as to be in contact with the display area DA. The polarizer POL is, for example, a circular polarizer. With the polarizer POL thus provided, it is possible to suppress the reflection of external light in the display area DA, for example.

The polarizer POL is provided with a cover member CG by means of an optical adhesive OCA1. The cover member CG can be, for example, a thin sheet of glass or plastic.

A protective member BPT is provided on a surface RF side of the display panel PNL. Of the surfaces of the protective member BPT, the surface in contact with the surface RF of the display panel PNL is the surface FB. The surface of the protective member BPT, which is opposite to the surface FB is referred to as a surface RB. The protective member DST is provided in contact with a part of the surface RB. The protective member BPT is disposed to mostly overlap the display area DA of the display panel PNL. More precisely, the protective member BPT is placed to overlap a part of the display area DA and the area EA.

Of the surfaces of the protective member DST, the surface in contact with the surface RB of the protective member BPT is referred to as a surface FP. The surface of the protective member DST, which is opposite to the surface FP is referred to as a surface RP. The protective member SPT is provided in contact with the surface RP. The protective member SPT overlaps the area BSF.

Of the surfaces of the protective member SPT, the surface in contact with the surface RP of the protective member DST is referred to as a surface FS. The surface of the protective member SPT, which is opposite to the surface FS is referred to as a surface RS. The surface RS is in contact with the surface RF (the surface RL of the substrate SUB1) of the area BSF of the display panel PNL.

The protective member BPT and the protective member SPT can be made of a plate-shaped resin material, for example, a plate-shaped polyethylene terephthalate (PET). The protective member BPT and the protective member SPT are adhered to the surface RF of the display panel PNL so as to oppose each other along the third direction Z while interposing the protective member DST therebetween. Thus, they function to protect the display panel PNL.

The protective member DST is a member having adhesive layers on a front surface and rear surface thereof, respectively, that is, for example, a double-sided tape. The protective member DST adheres the protective member SPT and the protective member BPT. Further, it is more preferable that the protective member DST be of a resin material having cushioning properties. The protective member DST has the function of keeping the gap between the bent portions of the display panels PNL to a certain level or more. With this configuration, even when pressure is applied to the display panel PNL in the thickness direction (third direction Z), the curvature of the area BND is kept within an acceptable range.

The protective member UVR is provided in contact with the surface FL in the area BND of the display panel PNL. The protective member UVR has a function of protecting the area BND, where the display panel PNL is bent. The protective member UVR is provided in contact with the surface FL of the display panel PNL between the end portion of the polarizer POL and the end portion EF11 of the flexible wiring board FPC.

The protective member UVR can be, for example, made of a photo-curing resin material. The protective member UVR is provided so as not to create a gap between the polarizer POL and itself. When a gap exists between the polarizer POL and the protective member UVR, the display panel PNL may break from the gap in the process of bending the display panel PNL, which may disconnect the wiring lines of the display panel PNL.

In the vicinity of the end portion ES12 of the display panel PNL, a protective member PRS is provided in contact with the end portion ES12, the protective member SPT, and the flexible wiring board FPC.

The protective member PRS can be, for example, of a resin material. The protective member PRS has a function of protecting the end portion ES12 of the display panel PNL.

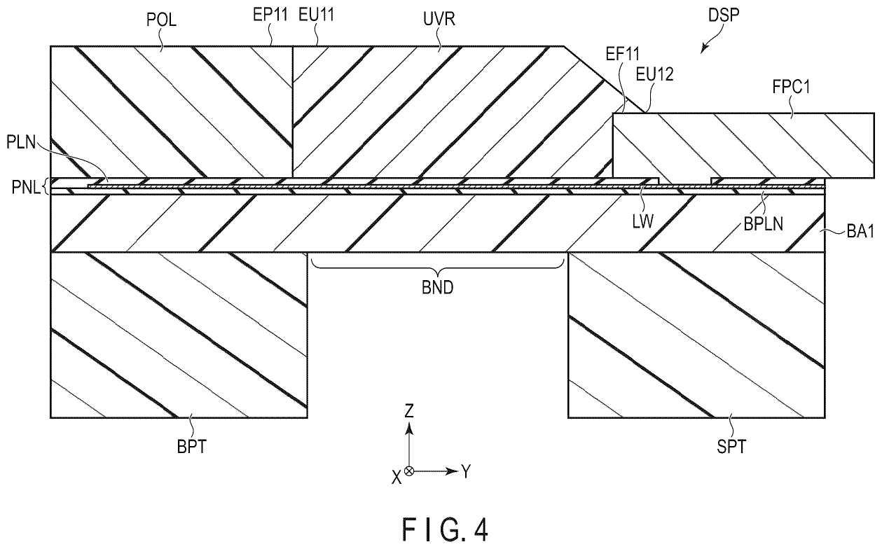

FIG. 4 is a partially enlarged cross-sectional view of what is shown in FIG. 2. FIG. 4 is a diagram showing a partially enlarged view from the vicinity of the end portion of the polarizer POL to the end portion EF11 of the flexible wiring board FPC1 of the display device DSP shown in FIG. 2 before being bent.

The display panel PNL shown in FIG. 4 comprises a base BA1, an insulating layer BPLN, a lead-out wiring line LW, and an insulating layer PLN. The insulating layer BPLN is provided to cover the base BA1. The lead-out wiring line LW is provided on the insulating layer BPLN. The insulating layer PLN is provided to cover the lead-out wiring line LW and the insulating layer BPLN.

The flexible wiring board FPC1 is connected to the lead-out wiring line LW via a contact hole made in the insulating layer PLN.

The base BA1 is a flexible base as described above. The base BA1 can be a resin film as described above.

The lead-out wiring line LW is a wiring line formed of a metal material. The lead-out wiring line LW is formed to have, for example, a three-layer stacked structure in which titanium (Ti), aluminum (Al), and titanium (Ti) are stacked in the listed order. But, the material of the lead-out wiring line LW is not limited to this. For example, it may be a single layer of tantalum (Ta), tungsten (W), molybdenum (Mo), copper (Cu), or silver (Ag) or a multilayer of any of these.

The insulating layer BPLN and the insulating layer PLN are each formed of an elastically deformable material. Examples of the elastically deformable materials include insulating resin materials of polyimide and acrylic. The elastic deformation will be described in detail later. The insulating layer BPLN and the insulating layer PLN have the function of planarizing these surfaces.

The protective member UVR comprises an end portion EU11 adjacent to the end portion EP11 of the polarizer POL and an end portion EU12 adjacent to the end portion EF11 of the flexible circuit board FPC.

The end portion EP11 and the end portion EU11 are in contact with each other.

As shown in FIGS. 2 and 4, the protective member UVR is provided so as not create a gap with respect to the polarizer POL. When a gap exists between the polarizer POL and the protective member UVR, the display panel PNL may be broken in the gap in the process of bending the display panel PNL, resulting in breaking of the wiring line of the display panel PNL.

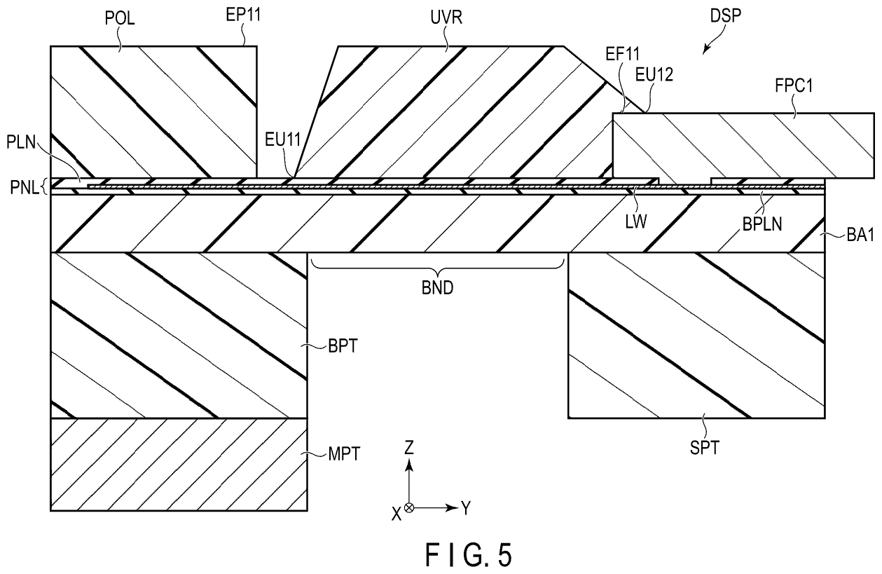

FIG. 5 is a cross-sectional view showing a display device of another comparative example. The display device DSP shown in FIG. 5 is different from the display device DSP shown in FIG. 4 in that the protective member UVR is disposed to be spaced apart from the polarizer POL.

In the display device DSP shown in FIG. 5, the end portion EU11 of the protective member UVR is spaced apart from the end portion EP11 of the polarizer POL. In FIG. 5, a reinforcing member MPT is provided in contact with the surface of the protective member BPT, which is opposite to the surface in contact with the base BA1.

The reinforcing member MPT is formed, for example, of a metal material or a reinforced plastic material. Here, the reinforcing member MPT is attached to the protective member BPT, and therefore the end portion EU11 of the protective member UVR is not bent.

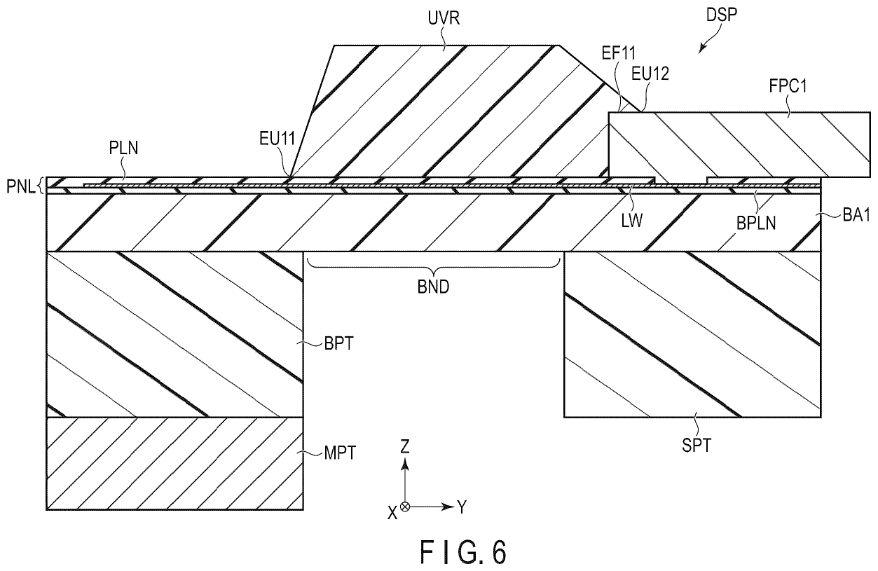

FIG. 6 is a cross-sectional view showing a display device of another comparative example. The display device DSP shown in FIG. 6 is different from the display device DSP shown in FIG. 4 in that a polarizer POL is not provided.

In the display device DSP shown in FIG. 6, color filters are provided on an array substrate (substrate SUB1) side of the display panel PNL. Therefore, in the display device DSP shown in FIG. 6, a polarizer is not required.

As shown in FIG. 6, the reinforcing member MPT is attached to the protective member BPT, and therefore the protective member UVR is not bent in the end portion EU11.

When the display device DSP is bent as shown

in FIG. 2, tensile stress is generated on a projecting side of the neutral plane (neutral axis) of the area BND, where the device is to be bent, according to the distance from the neutral plane. On the projection side of the neutral plane (neutral axis) of the area BND, compressive stress is generated according to the distance from the neutral plane.

However, when the protective member UVR is

formed of a plastically deformable material, the control of the neutral plane of the area BND is not substantially affected. When the protective member UVR is not made of a plastically deformable material, but of an elastically deformable material, that is, for example, a polyimide resin material or an acrylic resin material, the neutral surface of the area BND can be controlled.

The term “elasticity” used here is defined as the property of deforming when stress is applied and restoring the original shape when the stress is removed. On the other hand, the term “plasticity” used here is defined as the property of deforming when stress is applied and not restoring its original shape when the stress is removed. The plastic deformation is a deformation that does not restore its original shape when the stress is removed.

In the case where he protective member UVR is formed of a plastically deformable material, the original shape is not recovered even when the stress is removed once the protective member UVR is deformed by stressed. Therefore, in the display device DSP bent in the area BND, a neutral plane is created in the structural components including the protective member UVR.

In the case where the protective member UVR is formed of an elastic deformable material, even if the protective member UVR is deformed by stress applied thereto, it restores its original shape when the stress is removed. Therefore, in the display device DSP bent in the area BND, a neutral plane is generated in the component including the protective member UVR.

However, when the protective member UVR is

formed of an elastically deformable material such as a polyimide resin material, a gap may be generated between the polarizer POL and the protective member UVR. When such a gap is created, the protective member UVR may be bent at the end portion EU11, as described above.

In order to prevent the creation of a gap between the polarizer POL and the protective member UVR, it is preferable that the protective member UVR should be made of a material having plasticity. With a material having plasticity, once the material is deformed, it will not restore its original form, and therefore the protective member UVR will not peel off from the polarizer POL. Thus, in consideration of the adhesiveness with the polarizer POL, the protective member UVR should preferably be made of a plastically deformable material rather than an elastically deformable material.

However, if the protective member UVR is formed of a plastically deformable material, the protective member UVR does not affect the neutral plane NS, as described above. In such a case, the neutral plane NS may be created in an undesired area. Such a case will now be explained.

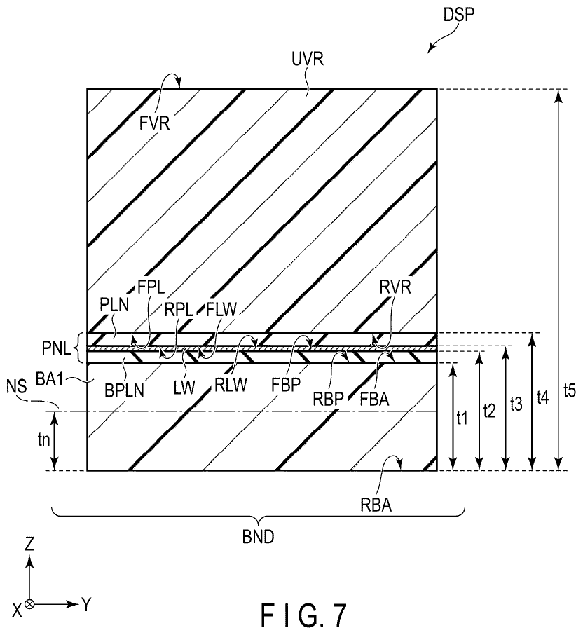

FIG. 7 is a partially enlarged cross-sectional view of the area BND, which is a bend area. In FIG. 7, of the surfaces of the base BA1, the insulating layer BPLN, the lead-out wiring line LW, the insulating layer PLN, and the protective member UVR, those located on a lower side are referred to as lower surface and those on an upper side are upper surfaces.

The lower surface and upper surface of the base BA1 are referred to as a lower surface RBA and an upper surface FBA, respectively. The lower surface and upper surface of the insulating layer BPLN are referred to as a lower surface RBP and an upper surface FBP, respectively. The lower surface and upper surface of the lead-out wiring line LW are referred to as a lower surface RLW and an upper surface FLW, respectively. The lower surface and upper surface of the insulating layer PLN are referred to as a lower surface RPL and an upper surface FPL, respectively. The lower surface and upper surface of the protective member UVR are referred to as a lower surface RVR and an upper surface FVR, respectively.

Here, the distance from the lower surface RBA to the upper surface FBA of the base BA1 along the third direction Z is defined as a length t1. The length t1 is the thickness of the base BA1.

Further the distance from the lower surface RBA of the base BA1 to the upper surface FBP of the insulating layer BPLN along the third direction Z is defined as a length t2. The length 2 is the sum of the thickness of the base BA1 and the thickness of the insulating layer BPLN.

Furthermore, the distance from the lower surface RBA of the base BA1 to the upper surface FLW of the lead-out wiring line LW along the third direction Z is defined as a length t3. The length t3 is the sum of the thickness of the base BA1, the thickness of the insulating layer BPLN, and the thickness of the lead-out wiring line LW.

Moreover, the distance from the lower surface RBA of the base BA1 to the upper surface FPL of the insulating layer PLN along the third direction Z is defined as a length t4. The length t4 is the sum of the thickness of the base BA1, the thickness of the insulating layer BPLN, the thickness of the lead-out wiring line LW, and the thickness of the insulating layer PLN. When the neutral plane NS (neutral axis) of

the area BND is obtained from the calculation, it can be understood that it is located inside the base BA1. Here, the distance from the lower surface RBA of the base BA1 to the neutral plane NS along the third direction Z is defined as a length tn. The length tn is less than the length t1 (tn<t1). The protective member UVR is formed of a plastically deformable material as described above and therefor does not affect the neutral plane NS.

To a part of the base BA1 placed below the neutral plane NS, is subjected to compressive stress. Another part of the base BA1, the insulating layer BPLN, the lead-out wiring line LW, and the insulating layer PLN, which are located above the neutral plane NS, are subjected to tensile stress.

In the area BND shown in FIG. 7, a neutral plane NS is created in the base BA1. Therefore, tensile stress acts on the lead-out wiring line LW, which is placed above the neutral plane NS, and therefore, undesirably, the lead-out wiring line LW may be broken due to tensile stress.

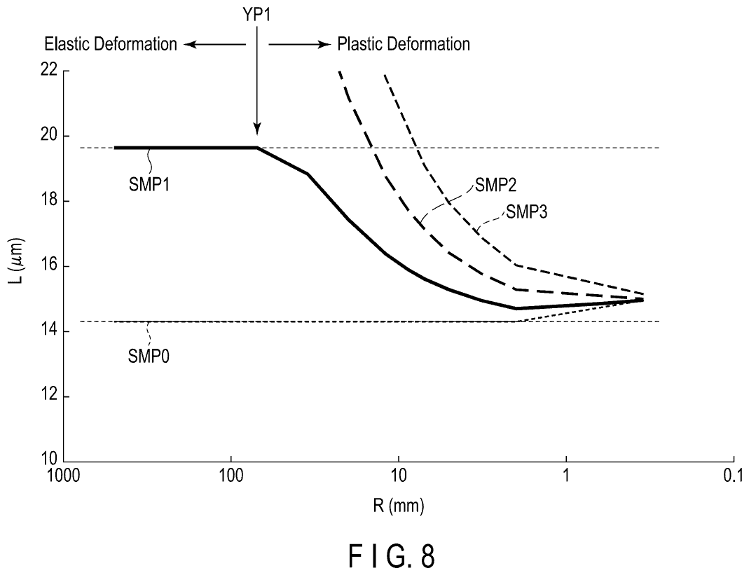

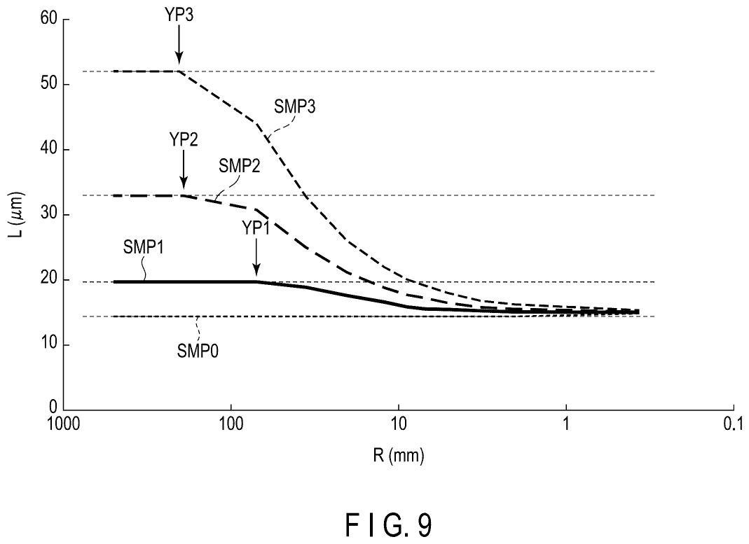

FIGS. 8 and 9 are each a diagram showing a relationship between the radius of curvature and the distance from the lower surface of the base to the neutral surface in the display device of the comparative example when it is bent. In FIG. 8, the horizontal axis indicates the radius of curvature R (mm) of the bent display device. In FIG. 9, the horizontal axis indicates the radius of curvature R (mm) of the bent display device. The vertical axis in each of FIGS. 8 and 9 indicates the distance L (μm) from the lower surface RBA of the base BA1 to the neutral plane NS along the third direction Z. FIG. 8 is a partially enlarged view of FIG. 9.

A plot SMP0 is a plot of the stacked structure of the display device DSP in the comparative example, in which the protective member UVR is not provided. A plot SMP1, plot SMP2, and plot SMP3 are plots of the stacked structures in which the thickness of the protective member UVR is 100 μm, 200 μm, and 300 μm, respectively.

As shown in FIG. 8, in the plot SMP1, elastic deformation occurs until the radius of curvature R becomes 70 mm, but when the radius of curvature R exceeds 70 mm, the deformation changes to plastic deformation. That is, at a radius of curvature R of 70 mm, it reaches a yield point YP1. The distance L at which the elastic deformation occurs is 19 (μm).

In the plot SMP0, neither elastic nor plastic deformation occurs.

In the plot SMP2 and plot SMP3, yield points (a yield point YP2 and a yield point YP3) are respectively obtained at a radius of curvature R of near 100 mm.

When bent with a bending deformation with a radius of curvature R of 1 mm or less, the plot SMP1 (a thickness of the protective member UVR of 100 μm) and the spot SMP3 (a thickness of the protective member UVR of 300 μm) converge at substantially the same position of the neutral plane as that of the plot SMP0 (no protective member UVR). Therefore, it can be said that the protective member UVR has no effect on the control of the neutral plane.

When an elastically deformable material layer is provided above or below the lead-out wiring line LW and the thickness of the elastically deformable material layer is adjusted so that the neutral plane is created in the lead-out wiring line LW, it is possible to suppress disconnection of the lead-out wiring line LW due to stress. Note that the position of the neutral plane can be changed as needed depending on the material of the base BA1, the material of the elastically deformable material layer, and other factors.

In the display device of this embodiment, the thickness of the insulating layer PLN formed above the lead-out wiring line LW is increased in order to cause a neutral surface created in the lead-out wiring line LW. When a neutral plane is created in the lead-out wiring line LW, stress does not substantially act in the lead-out wiring line LW, and therefore it is possible to prevent disconnection of the lead-out wiring line LW.

Further, the insulating layer PLN is a layer formed during the manufacturing process for the array substrate (substrate SUB1), and therefore the neutral plane can be controlled without increasing the processing steps of the manufacture. When the insulating layer PLN is a resin insulating layer of, for example, polyimide or acrylic, as described above, the thin film transistors (TFT) provided in the pixels PX are not affected by heat.

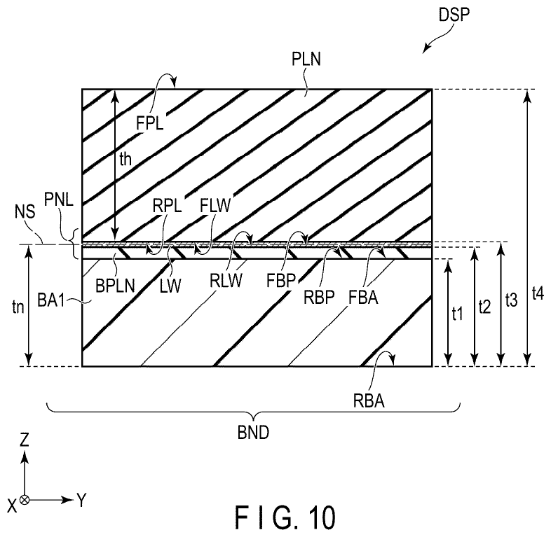

FIG. 10 is a diagram showing the relationship between the radius of curvature and the distance from the lower surface of the base to the neutral surface in the display device of the embodiment when it is bent. The display device DSP shown in FIG. 10 is different from the display device DSP shown in FIG. 7 in that an insulating layer PLN having a thicker film is provided in place of the protective member UVR.

The insulating layer PLN is formed of an elastically deformable material as described above. Therefore, a neutral plane NS is created in the stacked structure of the base BA1, the insulating layer BPLN, the lead-out wiring line LW, and the insulating layer PLN. Note that by controlling the thickness th of the insulating layer PLN, the length t4 from the lower surface RBA of the base BA1 to the upper surface FPL of the insulating layer PLN can be controlled. The length t4 is adjusted so as to create the neutral plane NS in the lead-out wiring line LW.

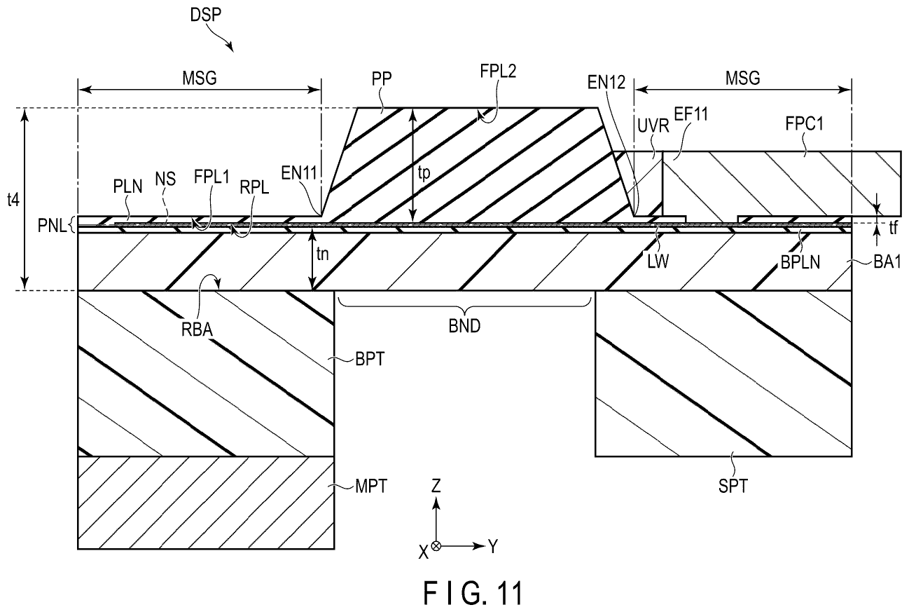

FIG. 11 is a cross-sectional view schematically showing an example of the configuration of the display device of the embodiment. The display device DSP shown in FIG. 11 comprises a thick-film region PP in part of the insulating layer PLN. The protective material UVR is provided between the region PP and the flexible wiring board FPC1.

As described above, the thick-film region PP is provided in a part of the insulating layer PLN so as to overlap the area BND, which is a bend area. Here, the region of the insulating layer PLN, which is other than the region PP is referred to as a region MSG. The distance from the lower surface RPL of the insulating layer PLN to the upper surface FPL1 of the region MSG along the third direction Z is defined as a length tf. The distance from the lower surface RPL of the insulating layer PLN to the upper surface FPL2 of the region PP along the third direction Z is defined as a length tp. The length tf and the length tp are the film thicknesses of the region MSG and the region PP, respectively. The length tf is less than the length tp (tf<tp). The length tp shown in FIG. 11 corresponds to the thickness th shown in FIG. 10.

Of the end portions of the region PP, the one close to the end portion EF11 of the flexible wiring board FPC1 is referred to as an end portion EN12. Of the end portions of the region PP, the one on an opposite side to the end portion EN12 in a direction opposite to the second direction Y is referred to as an end portion EN11.

When the length tp (thickness) of the region PP is 25 μm, the length tn from the lower surface RBA of the base BA1 to the neutral plane NS is 17.75 μm. In this case, the neutral plane NS is created in the lead-out wiring line LW. Therefore, no substantial stress is applied to the lead-out wiring line LW.

In the display device DSP shown in FIG. 11, a protective member UVR is also provided. But, it is disposed outside the area BND, which is the bend area. Therefore, the protective member UVR does not contribute to the control of the neutral plane.

In this embodiment, the protective member UVR is provided not after the formation of the array substrate, but it is formed by thickening a part of the insulating layer PLN during the formation of the array substrate. The insulating layer PLN is formed from an elastically deformable member. With this configuration, a neutral plane NS is created in the lead-out wiring line LW. Thus, since stress is not applied to the lead-out wiring line LW, and therefore there is no risk of disconnection. In this manner, it is possible to suppress a decrease in yield of the manufacturing of the display device DSP.

Here, the pixels PX of the display panel PNL will be explained in more detail.

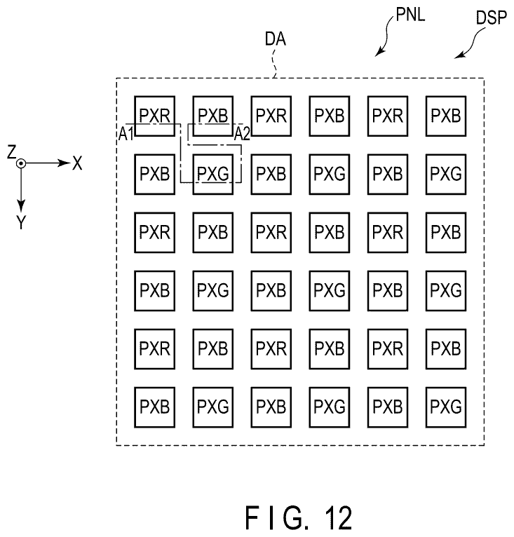

FIG. 12 is a partial plan view schematically showing an example of the configuration of the display panel. The plurality of pixels PX include pixels PXR which emit red color, pixels PXG which emit green color, and pixels PXB which emit blue color. The pixels PXR, pixels PXG, and pixels PXB may as well be referred to as first pixels, second pixels, and third pixels, respectively. The pixels PXR are each disposed adjacent to the respective pixel PXB along the first direction X and the second direction Y. The pixels PXG are each disposed adjacent to the respective pixel PXB along the first direction X and the second direction Y. The pixels PXB are each disposed adjacent to the respective pixel PXR along the first direction and adjacent to the respective pixel PXG along the second direction Y.

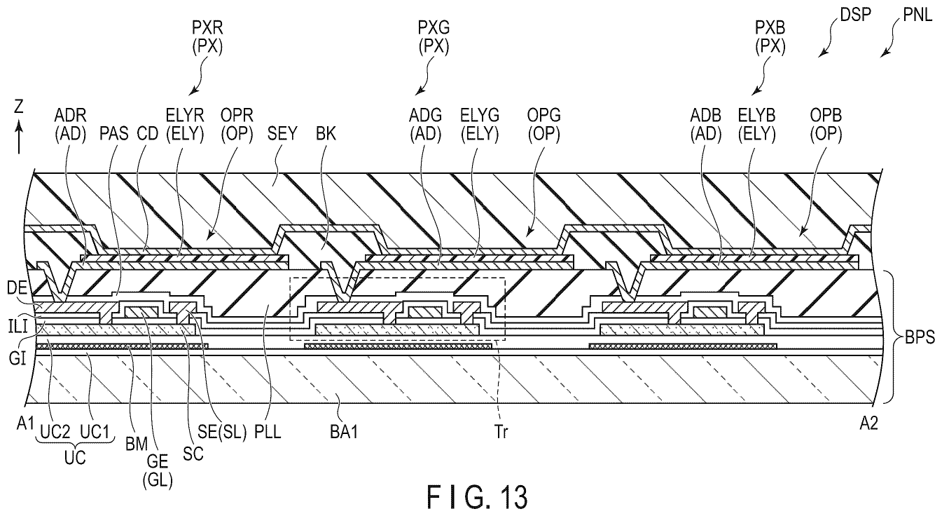

FIG. 13 is a cross-sectional view of the display panel shown taken along line A1-A2 in FIG. 12.

An example of the base BA1 is a base constituted by a resin film member as described above. The resin film member may be formed, for example, from a single layer of any of acrylic, polyimide, polyethylene terephthalate, polyethylene naphthalate, or the like, or a stacked body of layers of any of these.

On the base BA1, an insulating layer UC1 is provided. The insulating layer UC1 is formed from, for example, a single layer of each of or a stacked layer of a silicon oxide film and a silicon nitride film.

On the insulating layer UC1, a light-shielding layer BM may be provided so as to overlap a transistor Tr. The light-shielding layer BM suppresses changes in transistor characteristics due to light penetration and the like from the rear surface of the channel of the transistor Tr. When the light-shielding layer BM is formed of a conductive layer, it is also possible to impart a back-gate effect to the transistor Tr by providing a predetermined potential.

An insulating layer UC2 is provided to cover the insulating layer UC1 and the light-shielding layer BM. A material similar to that of the insulating layer UC1 can be used for the insulating layer UC2. The insulating layer UC2 can be made of a material different from that of the insulating layer UC1. For example, silicon oxide can be used for the insulating layer UC1 and silicon nitride can be used for the insulating layer UC2. The insulating layers UC1 and UC2 are collectively referred to as insulating layers UC.

On the insulating layer UC, a transistor Tr is provided. The transistor Tr includes a semiconductor layer SC, an insulating layer GI, a gate electrode GE (scanning line GL), an insulating layer ILI, a source electrode SE (signal line SL) and a drain electrode DE. The transistor Tr is a thin-film transistor (TFT).

As the semiconductor layer SC, amorphous silicon, polysilicon, or oxide semiconductor is used.

As the insulating layer GI, for example, silicon oxide or silicon nitride is provided in a single layer or in a stacked layer.

As the gate electrode GE, for example, a molybdenum-tungsten alloy (MoW) is used. The gate electrode GE may as well be formed to be integrated with the respective scanning line GL.

The insulating layer ILI is provided to cover the semiconductor layer SC and the gate electrode GE. The insulating layer ILI is formed, for example, from a single layer or a stacked layer of a silicon oxide layer and/or silicon nitride layer.

On the insulating layer ILI, a source electrode SE and a drain electrode DE are provided. The source electrode SE and the drain electrode DE are connected to the source region and drain region of the semiconductor layer SC, respectively, via contact holes made in the insulating layer ILI and the insulating layer GI. The source electrode SE may be formed to be integrated with the signal line.

An insulating layer PAS is provided to cover the source electrode SE, the drain electrode DE, and the insulating layer ILI. An insulating layer PLL is provided to cover the insulating layer PAS.

The insulating layer PAS is formed using an inorganic insulating material. Examples of the inorganic insulating material include a single layer of silicon oxide or silicon nitride or a stacked layer thereof. The insulating layer PLL is formed using an organic insulating material. Examples of the organic insulating material include resin insulating materials of polyimide and acrylic. With the insulating layer PLL thus provided, steps caused by the transistor Tr can be planarized.

An anode AD is provided on the insulating layer PLL. The anode AD is connected to the drain electrode DE via contact holes made in the insulating layer PAS and PLL. The anode provided in each pixel PXR is referred to as an anode ADR, the anode provided in each pixel PXB is referred to as an anode ADB, and the anode provided in each pixel PXG is referred to as an anode ADG. When there is no need to distinguish between the anode ADR, the anode ADG, and the anode ADB, they are simply referred to as anodes AD.

The anodes AD, for example, should be formed

from a stacked body of a reflective electrode and a transparent electrode. The reflective electrode is formed using a conductive material with high reflectivity, for example, silver (Ag) or aluminum (Al). The transparent electrode is formed using indium tin oxide (ITO) and indium zinc oxide (IZO), for example.

In this embodiment, the configuration from the base BA1 to the insulating layer PLL is defined as a backplane BPS.

Between each adjacent pair of anodes AD, a bank BK (which may as well be referred to as a projection portion or rib) is provided. As the material for the bank BK, an organic material similar to the material of the insulating layer PLL is used. The bank BK is opened to expose a part of the anode AD.

The aperture made in each pixel PXR is referred to as an aperture OPR, the aperture made in each pixel PXB is referred to as an aperture OPB, and the aperture made in each pixel PXG is referred to as an aperture OPG. When there is no need to distinguish between the aperture OPR, the aperture OPB, and the aperture OPG, they are simply referred to as apertures OP.

The end portion of the apertures OP should be gently tapered in cross-sectional view. If the end portion of the apertures OP has a steep shape, a coverage error may occur in the organic EL layer ELY, which is to be formed later.

The organic EL layer ELY is provided between each adjacent pair of banks BK so as to overlap the respective anode AD. The organic EL layer ELY includes a hole injection layer, a hole transport layer, an emission layer, an electron transport layer, and an electron injection layer. The organic EL layer ELY may further include an electron blocking layer, and a hole blocking layer, if necessary.

The organic EL layer provided in each pixel PXR is referred to as an organic EL layer ELYR, the organic EL layer provided in each pixel PXB is referred to as an organic EL layer ELYB, and the organic EL layer provided in each pixel PXG is referred to as an organic EL layer ELYG. When there is no need to distinguish between the organic EL layer ELYR, the organic EL layer ELYG, and the organic EL layer ELYB, they are simply referred to as organic EL layers ELY.

A cathode CD is provided on each organic EL layer ELY. The cathode CD is formed, for example, using a magnesium-silver alloy (MgAg) film, a single-layered film of silver (Ag), or a stacked body film of silver (Ag) and a transparent conductive material or the like. For example, indium tin oxide (ITO), indium zinc oxide (IZO) or the like can be used as the transparent conductive material.

An insulating layer SEY is provided to cover the cathodes CD. The insulating layer SEY has the function of preventing moisture from entering the organic EL layer ELY from the outside. As the insulating layer SEY, a material with high gas barrier property is suitable. As the insulating layer SEY, for example, an insulation layer formed by interposing an organic insulating layer between two inorganic insulating layers containing nitrogen can be used. The material of the organic insulating layer can be a resin insulating material of polyimide or acrylic. The material of the inorganic insulating layers containing nitrogen can be, for example, silicon nitride or aluminum nitride.

The insulating layer PLL shown in FIG. 13 corresponds to the insulating layer BPLN shown in FIG. 11. The insulating layer SEY shown in FIG. 13 corresponds to insulating layer PLN shown in FIG. 11. When the insulating layer SEY is formed from an insulating layer in which an organic insulating layer is interposed between two inorganic insulating layers, the thickness of the organic insulating layer can be controlled, and thus the length tp (thickness) of the region PP can be controlled.

The light emission generated in the organic EL layer ELY is extracted upward via the respective cathode CD. In other words, the display device DSP (display panel PNL) of this embodiment has a top emission structure.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A display device comprising:
a flexible base;
a first insulating layer provided on the base;
a wiring line provided on the first insulating layer; and
a second insulating layer which covers the wiring line and the first insulating layer, wherein
the display device includes a display area and an end portion region including a bend area,
the second insulating layer includes a first region having a first thickness and a second region having a second thickness greater than the first thickness,
the second region overlaps the bend area, and
a neutral plane of a stacked structure of the base, the first insulating layer, the wiring line, and the second insulating layer are formed in the wiring line.

2. The display device according to claim 1, wherein
the second insulating layer is formed of an elastically deformable material.

3. The display device according to claim 2, wherein
the elastically deformable material is a resin insulating material of polyimide or acrylic.

4. The display device according to claim 1, wherein
the base is a resin film member of acrylic, polyimide, polyethylene terephthalate, or polyethylene naphthalate.

5. The display device according to claim 1, wherein
the first insulating layer is formed of an elastically deformable material.

6. The display device according to claim 5, wherein
the elastically deformable material is a resin insulating material of polyimide or acrylic.

7. The display device according to claim 1, wherein
the wiring line is formed from a single layer of titanium (Ti), aluminum (Al), tantalum (Ta), tungsten (W), molybdenum (Mo), copper (Cu), or silver (Ag), or a stacked layer of any combination thereof.

8. The display device according to claim 1, further comprising:
a plurality of pixels disposed in the display area, wherein
each of the plurality of pixels includes an organic EL layer.
